(19) United States
(12) Patent Application Publication
(10) Pub. No.: US 2014/0209867 A1
(43) Pub. Date: Jul. 31, 2014

(54) Sulfonyl Group-Contained Compound and Organic Electroluminescent Device Using Sulfonyl Group-Contained Compound and Preparation Method Thereof

(71) Applicant: Qinghua Zou, Shenzhen City (CN)

(72) Inventor: Qinghua Zou, Shenzhen City (CN)

(73) Assignee: Shenzhen China Star Optoelectronics Technology Co., Ltd., Senzhen, Guangdong (CN)

(21) Appl. No.: 13/823,751

(22) PCT Filed: Jan. 29, 2013
(86) PCT No.: PCT/CN2013/071066

§ 371 Date: Mar. 15, 2013

(30) Foreign Application Priority Data
Jan. 25, 2013 (CN) 201310031685.1

(51) Int. Cl. H01L 51/00

(52) U.S. Cl. CPC H01L 51/0074; H01L 51/001; H01L 51/0067
USPC 257/40; 438/46; 549/41; 546/256

(57) ABSTRACT

The present invention provides a sulfonyl group-contained compound, organic electroluminescent device using the same, and a preparation method thereof. The sulfonyl group-contained compound is presented by the following formula:

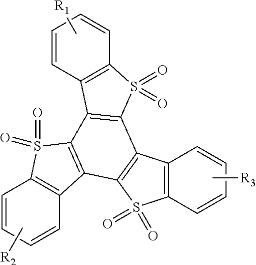

in which R₁, R₂, and R₃ are alkyl groups, aromatic ring groups, —CN or —OCH₃ and R₁, R₂, and R₃ are linked in position 2 or 3 of benzene ring. The sulfonyl group-contained compound of the present invention combines three thiofluorenes to form a novel sulfonyl group-contained compound with dendrimer structure, which combines properties of electron affinity and electron transportation of thiofluorene and also combines dimension property of dendrimer structure. When the sulfonyl group-contained compound is used in a light-emitting layer or an electron transport layer of an organic electroluminescent device, the efficiency and the lifespan of the organic electroluminescent device can be increased.

### BACKGROUND OF THE INVENTION

1. Field of the Invention

The present invention relates to the field of organic electroluminescence, and in particular to an electron transporting material.

2. The Related Arts

An organic light-emitting diode (OLED) is a self-luminescent device, which shows various advantages, such as low voltage, wide view angle, fast response, and excellent temperature adaptability, and is a next-generation display technology. Few manufacturers have already manufactured OLED panels in mass production and other manufacturers are also devoted themselves to development and mass production.

The principle of organic electroluminescent devices is that under the action of an electric field, electrical holes and electrons are respectively injected from an anode and a cathode and are respectively driven through a hole injection layer and a hole transporting layer and an electron injection layer and an electron transporting layer to re-combine with each other in an emissive layer to form excitons, which are subjected to radiation decay to emit light.

A key factor to increase the efficiency and lifespan of the organic electroluminescent device is the balance of concentrations of hole carriers and electron carriers in the emissive layer. The conventionally used electron transporting material has electron mobility that is approximately 10⁻⁵ cm² v⁻¹ s⁻¹ to 10⁻⁶ cm² v⁻¹ s⁻¹ and hole transporting material currently used has a hole mobility that is approximately 10⁻² cm² v⁻¹ s⁻¹ to 10⁻² cm² v⁻¹ s⁻¹. The difference of mobility in these two function layer materials is around 1,000 times. This makes the concentrations of hole carriers and electron carriers in an emissive layer of a device made with the materials not balanced with respect to each other and the recombination zone will shift toward the anode. The excessive hole carriers in the emissive layer may also cause quenching of the excitons, lowering the efficiency of the device and severely suppressing the efficiency and lifespan of the organic electroluminescent device.

To obtain devices that are of high efficiency and long lifespan, the electron transporting material must meet the following requirements: having higher electron mobility, having higher electron affinity, having stronger electron acceptability, and being easy to transport electron.

Thiofluorene is a novel electron-defect compound, which is regarded as a fluorine derivative and is equivalent to a fluorine by which C-9 position is substituted by a sulfonyl group (—SO₂). Sulfonyl is an electron withdrawing group, and therefore, thiofluorene has a higher electron affinity, and its energy band gap is about 2.8 eV that is beneficial for electron injection and transportation. S atom is in the highest valance state and has a better anti-oxidation ability, and thiofluorene also has strong thermal stability. All these advantages make thiofluorene a valuable electron transporting material.

Due to having a unique structure, a compound with dendrimer molecular structure shows high molecule, high steric hindrance, high glass transition temperature, power molecule crystallization, and being easy to form a stable amorphous layer. Compounds of this type that have been published include:

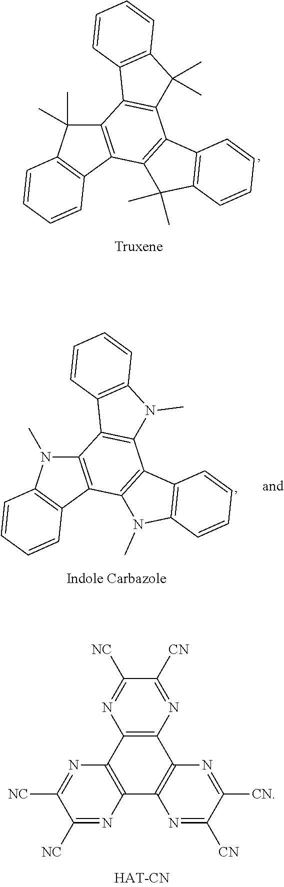

### SUMMARY OF THE INVENTION

An object of the present invention is to provide a sulfonyl group-contained compound, which combines three thiofluorenes to form a novel sulfonyl group-contained compound with dendrimer structure, which combines properties of electron affinity and electron transportation of thiofluorene together, and also combines the dimension property of dendrimer structure.

Another object of the present invention is to provide an organic electroluminescent device that uses sulfonyl contained compound, wherein a light-emitting layer or an electron transporting layer comprises a sulfonyl contained compound to facilitate injection and transportation of electron, so as to form a stable amorphous layer and to increase the efficiency and lifespan of the organic electroluminescent device.

A further object of the present invention is to provide a preparation method of organic electroluminescent device using sulfonyl contained compound, which, through adding a sulfonyl contained compound in a light-emitting layer or an electron transporting layer, facilitates injection and transportation of electrons of the electroluminescent device so as to form a stable amorphous layer and increase the efficiency and lifespan of the organic electroluminescent device.

To achieve the objects, the present invention provides a sulfonyl contained compound having the following formula:

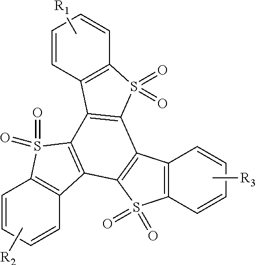

in which R₁, R₂, and R₃ are an alkyl group, an aromatic ring group, a heterocyclic ring group, —CN or —OCH₃; and R₁, R₂, and R₃ are linked in position 2 or 3 of the benzene ring.

The alkyl group is a branched alkyl group or a linear alkyl group.

The branched alkyl group is

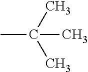

and the linear alkyl group is

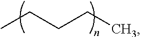

wherein n is an integer of 1 to 8.

The aromatic group is

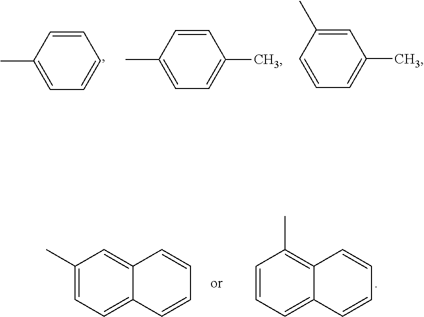

The heterocyclic ring group is

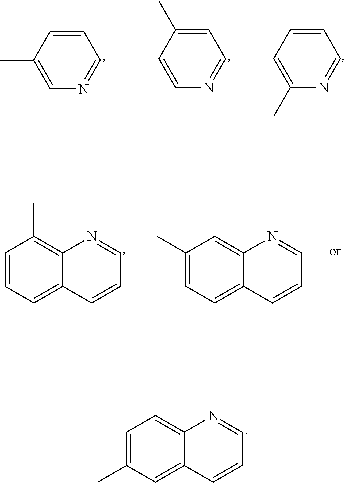

The present invention also provides an organic electroluminescent device using sulfonyl group-contained compound, which comprises: a transparent substrate, an anode arranged on the transparent substrate, a hole transporting layer arranged on the anode, a light-emitting layer arranged on the hole transporting layer, an electron transporting layer arranged on the light-emitting layer, and a cathode arranged on the electron transporting layer; wherein at least one of the electron transport layer and the light-emitting layer comprises the sulfonyl group-contained compound.

The sulfonyl group-contained compound is represented by the following formula:

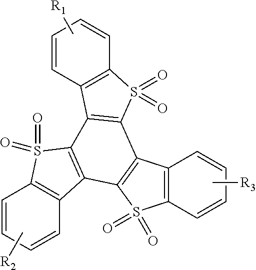

in which R₁, R₂, and R₃ are an alkyl group, an aromatic ring group, a heterocyclic ring group, —CN or —OCH₃; and R₁, R₂, and R₃ are linked in position 2 or 3 of the benzene ring.

When the light-emitting layer comprises the sulfonyl group-contained compound, the sulfonyl group-contained compound is used as a single host material of the light-emitting layer or an ingredient of host material of the light-emitting layer. When the sulfonyl group-contained compound is used as an ingredient of the host material of the light-emitting layer, the compound is in an amount of 1%-99% of the total weight of the host material of the light-emitting layer

When the electron transport layer comprises the sulfonyl group-contained compound, the electron transport layer comprises a single layer or at least two layers, each layer of the electron transport layer comprising the sulfonyl group-contained compound, the sulfonyl group-contained compound being used as a single material of the electron transport layer or an ingredient of the material of the electron transport layer. When the sulfonyl group-contained compound is used as an ingredient of the material of the electron transport layer, the sulfonyl group-contained compound is in an amount of 1%-99% of the total weight of the material of the electron transport layer.

The present also provides a preparation method of organic electroluminescent device using sulfonyl group-contained compound, which comprises the following steps:

(1) providing a transparent substrate;

(2) forming an anode on the transparent substrate;

(3) forming at least one hole transporting layer on the anode;

(4) forming at least one light-emitting layer on the hole transporting layer;

(5) forming at least one electron transporting layer on the light-emitting layer; and

(6) forming a cathode on the electron transporting layer;

wherein at least one of the light-emitting layer and electron transporting layer comprise the sulfonyl group-contained compound.

Step (4) further comprises depositing the sulfonyl group-contained compound on the hole transporting layer by vacuum evaporation, the sulfonyl group-contained compound being used as a single host material of the light-emitting layer or an ingredient of the host material of the light-emitting layer. When the sulfonyl group-contained compound is used as an ingredient of the host material of the light-emitting layer, the sulfonyl group-contained compound is in an amount of 1%-99% of the total weight of the host material of the light-emitting layer.

Step (5) further comprises depositing the sulfonyl group-contained compound that is used as the material of the electron transporting layer on the light-emitting layer by vacuum evaporation, the sulfonyl group-contained compound being used as a single material of the electron transporting layer or an ingredient of the material of the electron transporting layer. When the sulfonyl group-contained compound is used as an ingredient of the material of the electron transporting layer, the sulfonyl group-contained compound is in an amount of 1%-99% of the total weight of the material of the electron transport layer.

The efficacy of the present invention is that the present invention provides a sulfonyl group-contained compound that combines three thiofluorenes to form a novel sulfonyl group-contained compound with dendrimer structure, which combines properties of electron affinity and electron transportation of thiofluorene together, and also combines the dimension property of dendrimer structure. When the sulfonyl group-contained compound is used for light-emitting layer and electron transporting layer of an organic electroluminescent device, the efficiency and lifespan of the organic electroluminescent device can be increased.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as beneficial advantages, of the present invention will be apparent from the following detailed description of an embodiment of the present invention, with reference to the attached drawings. In the drawings:

FIG. 1 shows a schematic diagram of 2,2′,2″-tri(3-pyridyl)trithiofluorene of a first embodiment;

FIG. 2 shows a NMR (H1) spectroscopy of 2,2′,2″-tri(3-pyridyl)trithiofluorene of Embodiment 1;

FIG. 3 shows a NMR (C13) spectroscopy of 2,2′,2″-tri(3-pyridyl)trithiofluorene of Embodiment 1;

FIG. 4 shows a schematic diagram of organic Electroluminescent device adapting a sulfonyl group-contained compound; and

FIG. 5 shows a flow chart of preparing an electroluminescent device with sulfonyl group-contained compound.

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

The present invention provides a sulfonyl group-contained compound, represented by the following formula:

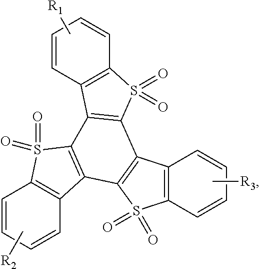

in the above formula, R₁, R₂, and R₃ are alkyl group, aromatic ring group, or heterocyclic ring group. R₁, R₂, and R₃ are respectively linked to position 2 or 3 of the benzene ring.

The alkyl group can be a branched alkyl group, such as

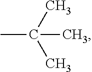

or a linear alkyl group, such as

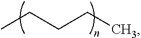

wherein n is an integer of 1 to 8.

The aromatic group is

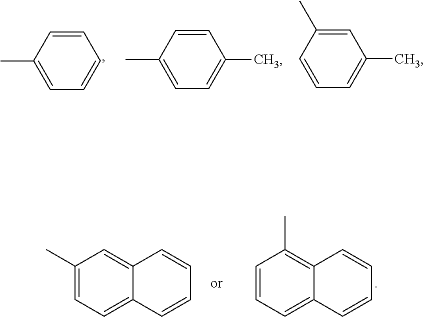

The heterocyclic ring group is

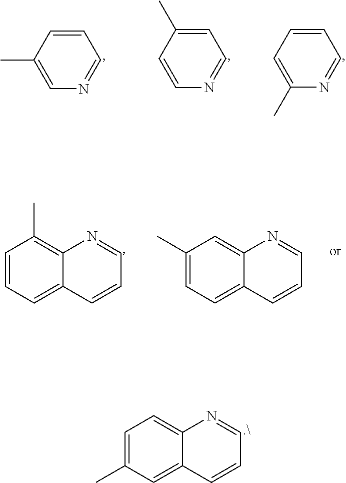

R₁, R₂, and R₃ are not limited to the above three groups. For example, R₁, R₂, and R₃ can be CN or —OCH₃.

The sulfonyl group-contained compound in the present invention is produced according to the following synthesis route. Firstly, terfluorene is synthesized, and then through regular reactions, the moieties represented by R₁, R₂, and R₃ substitute —H and are linked in position 2 or 3 of the benzene ring. The synthesis route of TFSO is shown as follows:

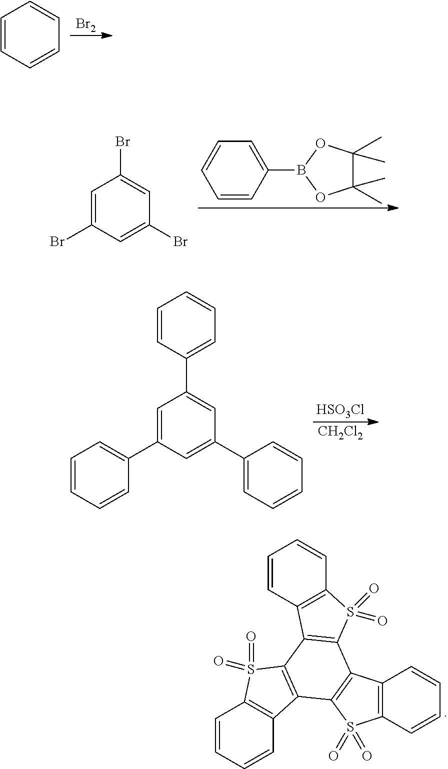

### Preparation of Tribromobenzene

Benzene of 10 mol is poured into a 500 ml three-necked flask and 200 ml CHCl₃ and 0.4 g iron powder are added with stirring until dissolved. The mixture is chilled in ice bath at 0° C. and protected from light, with a mixture solution of 35 mol bromine liquid and 80 ml CHCl₃ slowly dripping therein for reaction in room temperature for 10 hours until yellow-brown solid precipitates. After the reaction is finished, saturated NaHSO₃ solution is added to remove unreacted bromine. Crude product is washed twice with saturated NaHSO₃ solution, dried, and re-crystallized for purification to thereby obtain slight yellow-brown powder.

### Preparation of 1,3,5-Triphenyl Benzene

Benzeneboronic acid of 40 mol, tribromobenzene of 10 mol, palladium acetate (30 mg), and tricyclohexyl phosphine (60 mg) are added into a flask and high-refined toluene of 100 m, tetraethylammonium hydroxide solution (quality score is 20%) of 30 ml, and deionized water of 30 ml are also added under argon protection. The mixture is then heated to 80-85° C. for reaction for 24 hours. Then the reaction is stopped, followed by chilling and being dropped with methanol for precipitation, filtration, column chromatography, and drying.

### Preparation of Trithiofluorene (TFSO)

A mount of 10 mol 1,3,5-triphenyl benzene is added into a flask and dissolved in 100 ml methylene chloride, and chilled in ice bath until the system is less than 50° C. The mixture is then dropped with 80 mol chlorosulfonic acid for reaction for 12 hours in room temperature. After completion of the reaction, iced water is slowly added and saturated NaHSO₃ solution is also added. The mixture of reaction is directly filtered to obtain a large quantity of solid, and the crude product is then washed with saturated NaHSO₃ solution, followed by column chromatography and drying.

Regular reaction is subsequently performed so that the moieties represented by R₁, R₂, and R₃ substitute —H and linked in position 2 or 3 of the benzene ring. R₁, R₂ and R₃ represent various moieties and the methods used here are conventional, so that the details are not addressed herein.

Because sulfonyl group-contained compounds of this type have sulfonyl groups serving as electron withdrawing groups, they have a good electron affinity and electron transport property, which are suitable for being used as a light-emitting layer or an electron transporting layer to increase efficiency of organic electroluminescent device. Further, sulfonyl group-contained compounds have a dendrimer structure that has properties such as high-molecular weight, high-stereo hindrance, high-glass transition temperature, low-crystallinity, it is easier to form a stable amorphous film and extend the lifespan of the organic electroluminescent device. The sulfonyl group-contained compound of the present invention can be utilized in the fields of organic photovoltaic (OPV) and organic thin film transistors (OTFT).

The present invention will be described with reference to the following embodiments, and the present invention is not limited to theses embodiments.

### Embodiment 1: Preparation of 2,2′,2″-Tri(3-Pyridyl)Trithiofluorene

Synthesis route is shown as follows:

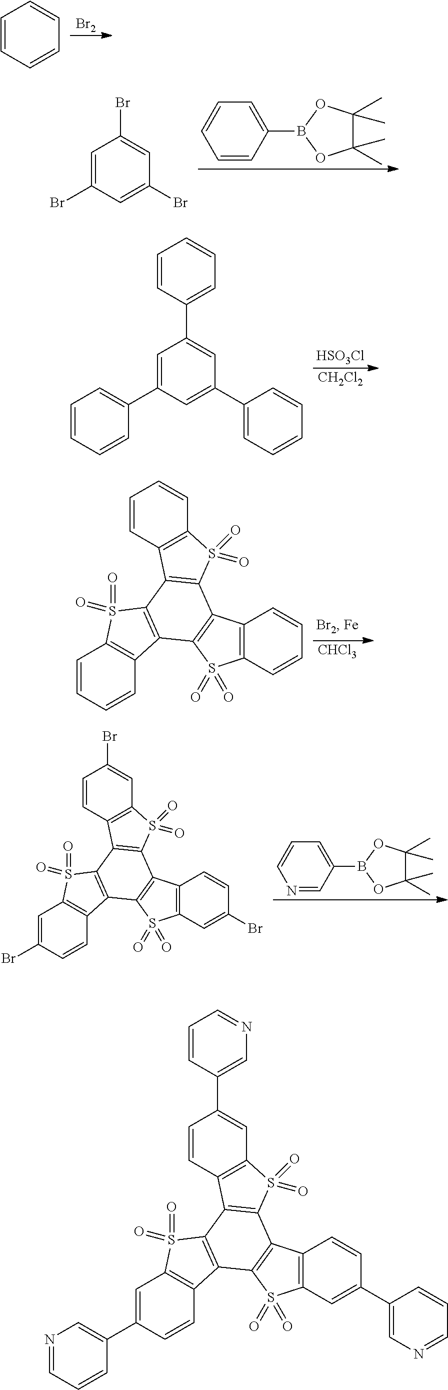

### Preparation of Tribromobenzene

Benzene of 10 mol is poured into a 500 ml three-necked flask and 200 ml CHCl₃ and 0.4 g iron powder are added with stirring until dissolved. The mixture is chilled in ice bath at 0° C. and protected from light, with a mixture solution of 35 mol bromine liquid and 80 ml CHCl₃ slowly dripping therein for reaction in room temperature for 10 hours until yellow-brown solid precipitates. After the reaction is finished, saturated NaHSO₃ solution is added to remove unreacted bromine. Crude product is washed twice with saturated NaHSO₃ solution, dried, and re-crystallized for purification to thereby obtain slight yellow-brown powder.

### Preparation of 1,3,5-Triphenyl Benzene

Benzeneboronic acid of 40 mol, tribromobenzene of 10 mol, palladium acetate (30 mg), and tricyclohexyl phosphine (60 mg) are added into a flask and high-refined toluene of 100 m, tetraethylammonium hydroxide solution of 30 ml, and deionized water of 30 ml are also added under argon protection. The mixture is then heated to 80-85° C. for reaction for 24 hours. Then the reaction is stopped, followed by chilling and being dropped with methanol for recipitation, filtration, column chromatography, and drying.

### Preparation of Trithiofluorene (TFSO)

A mount of 10 mol 1,3,5-triphenyl benzene is added into a flask and dissolved in 100 ml methylene chloride, and chilled in ice bath until the system is less than 50° C. The mixture is then dropped with 80 mol chlorosulfonic acid for reaction for 12 hours in room temperature. After completion of the reaction, iced water is slowly added and saturated NaHSO₃ solution is also added. The mixture of reaction is directly filtered to obtain a large quantity of solid, and the crude product is then washed with saturated NaHSO₃ solution, followed by column chromatography and drying.

### Preparation of 2,2′,2″-Tribromotrithiofluorene

An amount of 5 mol trithiofluorene is poured into a three-neck flask and added with CHCl₃ and 0.2 g with stirring until dissolved, and then chilled in ice bath at 0° C. and protected from light, with a mixture solution of 18 mol bromine liquid and 40 ml CHCl₃ slowly dripping for reaction in room temperature for 10 hours. After the reaction is completed, saturated NaHSO₃ solution is added to remove unreacted bromine. Crude product is washed twice with saturated NaHSO₃ solution, followed by drying and re-crystallization for purification.

### Preparation of 2,2′,2″-Tri(3-Pyridyl)Trithiofluorene

An amount of 20 mol 2-boronic acid pinacol ester, 5 mol 2,2′,2″-tribromotrithiofluorene, palladium acetate (15 mg), tricyclohexyl phosphine (30 mg) were added into a flask, and 100 ml high-refined toluene, 20 ml tetraethylammonium hydroxide solution (quality score is 20%), and 30 ml deionized water are also added under argon protection, followed by heating 80-85° C. for reaction for 24 hours. Then the reaction is stopped, followed by chilling and being dropped with methanol for precipitation, filtration, column chromatography, and drying.

### Embodiment 2: Preparation of 2,2′,2″-Triphenyl Trithiofluorene

Synthesis route is shown as follow:

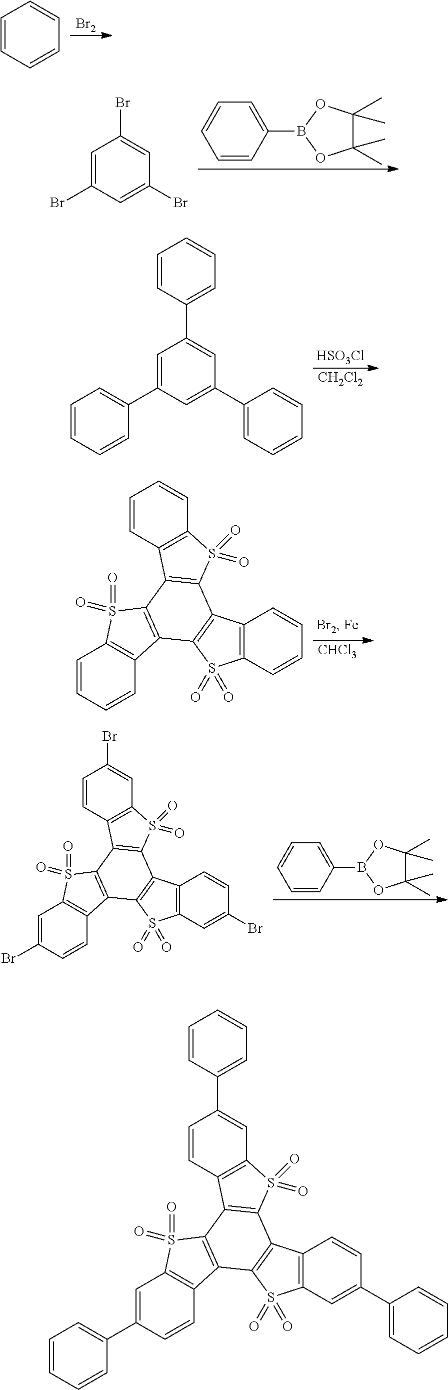

### Preparation of Tribromobenzene

Benzene of 10 mol is poured into a 500 ml three-necked flask and 200 ml CHCl₃ and 0.4 g iron powder are added with stirring until dissolved. The mixture is chilled in ice bath at 0° C. and protected from light, with a mixture solution of 35 mol bromine liquid and 80 ml CHCl₃ slowly dripping therein for reaction in room temperature for 10 hours until yellow-brown solid precipitates. After the reaction is finished, saturated NaHSO₃ solution is added to remove unreacted bromine. Crude product is washed twice with saturated NaHSO₃ solution, dried, and re-crystallized for purification to thereby obtain slight yellow-brown powder.

### Preparation of 1,3,5-Triphenyl Benzene

Benzeneboronic acid of 40 mol, tribromobenzene of 10 mol, palladium acetate (30 mg), and tricyclohexyl phosphine (60 mg) are added into a flask and high-refined toluene of 100 m, tetraethylammonium hydroxide solution of 30 ml, and deionized water of 30 ml are also added under argon protection. The mixture is then heated to 80-85° C. for reaction for 24 hours. Then the reaction is stopped, followed by chilling and being dropped with methanol for recipitation, filtration, column chromatography, and drying.

### Preparation of Trithiofluorene (TFSO)

A mount of 10 mol 1,3,5-triphenyl benzene is added into a flask and dissolved in 100 ml methylene chloride, and chilled in ice bath until the system is less than 50° C. The mixture is then dropped with 80 mol chlorosulfonic acid for reaction for 12 hours in room temperature. After completion of the reaction, iced water is slowly added and saturated NaHSO₃ solution is also added. The mixture of reaction is directly filtered to obtain a large quantities of solid, and the crude product is then washed with saturated NaHSO₃ solution, followed by column chromatography and drying.

### Preparation of 2,2′,2″-Tribromotrithiofluorene

An amount of 5 mol trithiofluorene is poured into a three-neck flask and added with CHCl₃ and 0.2 g with stirring until dissolved, and then chilled in ice bath at 0° C. and protected from light, with a mixture solution of 18 mol bromine liquid and 40 ml CHCl₃ slowly dripping for reaction in room temperature for 10 hours. After the reaction is completed, saturated NaHSO₃ solution is added to remove unreacted bromine. Crude product is washed twice with saturated NaHSO₃ solution, followed by drying and re-crystallization for purification.

### Preparation of 2,2′,2″-Triphenyl Trithiofluorene

An amount of 20 mol boric acid triphenyl ester, 5 mol 2,2′,2″-tribromotrithiofluorene, palladium acetate (15 mg), and tricyclohexyl phosphine (30 mg) are added into a flask, and 100 ml high-refined toluene, 20 ml tetraethylammonium hydroxide solution (quality score is 20%), and 30 ml deionized water are also added under argon protection, followed by heating heated to 80-85° C. for reaction for 24 hours. Then the reaction is stopped, followed by chilling and being dropped with methanol for precipitation, filtration, column chromatography, and drying.

### Embodiment 3: 2,2′,2″-Tri-Tert-Butyl Trithiofluorene

Synthesis route is shown as follow:

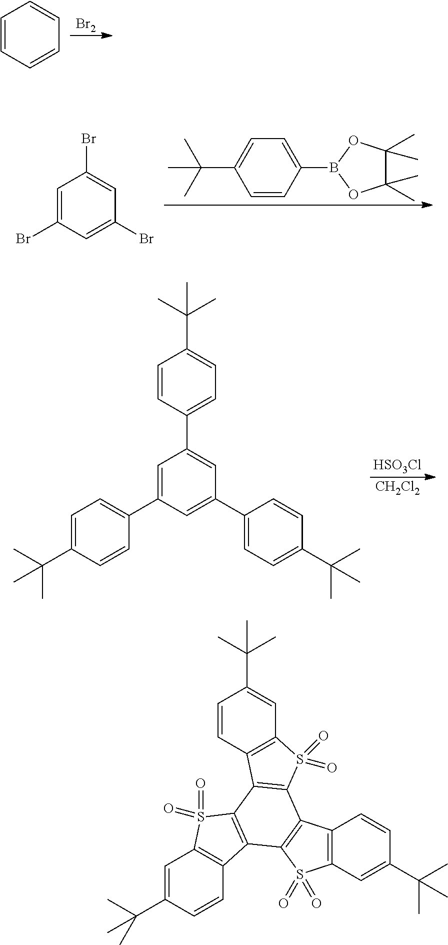

### Preparation of Tribromobenzene

Benzene of 10 mol is poured into a 500 ml three-necked flask and 200 ml CHCl₃ and 0.4 g iron powder are added with stirring until dissolved. The mixture is chilled in ice bath at 0° C. and protected from light, with a mixture solution of 35 mol bromine liquid and 80 ml CHCl₃ slowly dripping therein for reaction in room temperature for 10 hours until yellow-brown solid precipitates. After the reaction is finished, saturated NaHSO₃ solution is added to remove unreacted bromine. Crude product is washed twice with saturated NaHSO₃ solution, dried, and re-crystallized for purification to thereby obtain slight yellow-brown powder.

### Preparation of 1,3,5-Tri-Tert-Butyl Phenylbenzene

Tert-butyl benzeneboronic acid of 40 mol, tribromobenzene of 10 mol, palladium acetate (30 mg), and tricyclohexyl phosphine (60 mg) are added into a flask and high-refined toluene of 100 m, tetraethylammonium hydroxide solution of 30 ml, and deionized water of 30 ml are also added under argon protection. The mixture is then heated to 80-85° C. for reaction for 24 hours. Then the reaction is stopped, followed by chilling and being dropped with methanol for precipitation, filtration, column chromatography, and drying.

### Preparation of 2,2′,2″-Tri-Tert-Butyl Trithiofluorene

A mount of 10 mol 1,3,5-tri-tert-butyl phenylbenzene is added into a flask and dissolved in 100 ml methylene chloride, and chilled in ice bath until the system is less than 50° C. The mixture is then dropped with 80 mol chlorosulfonic acid for reaction for 12 hours in room temperature. After completion of the reaction, iced water is slowly added and saturated NaHSO₃ solution is also added. The mixture of reaction is directly filtered to obtain a large quantities of solid, and the crude product is then washed with saturated NaHSO₃ solution, followed by column chromatography and drying.

Taking 2,2′,2″-tri(3-pyridyl)trithiofluorene synthesized in Embodiment 1 as an example to analyze sulfonyl group-contained compound of the present invention.

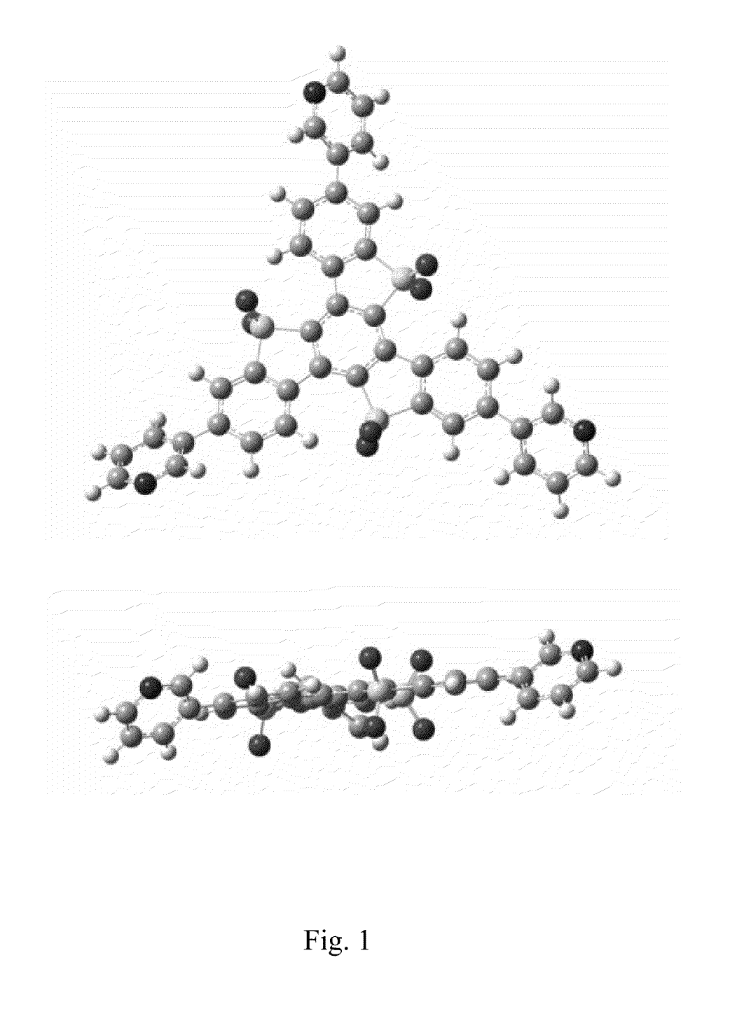

The structural formula diagram of 2,2′,2″-tri(3-pyridyl)trithiofluorene of Embodiment 1 is shown in FIG. 1, and the diagram includes front view and side view diagrams that are the result of simulation with Gaussian 09 software.

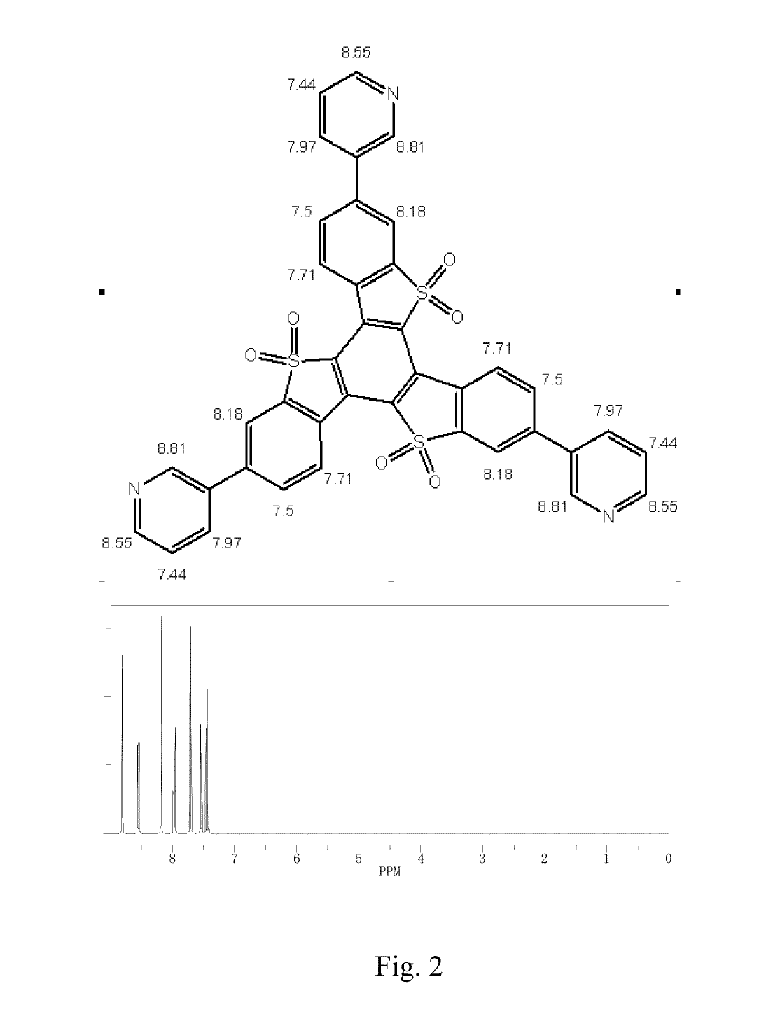

NMR (H-1) spectroscopy is shown in FIG. 2, and NMR data is the result of simulation with Chemdraw2004 software.

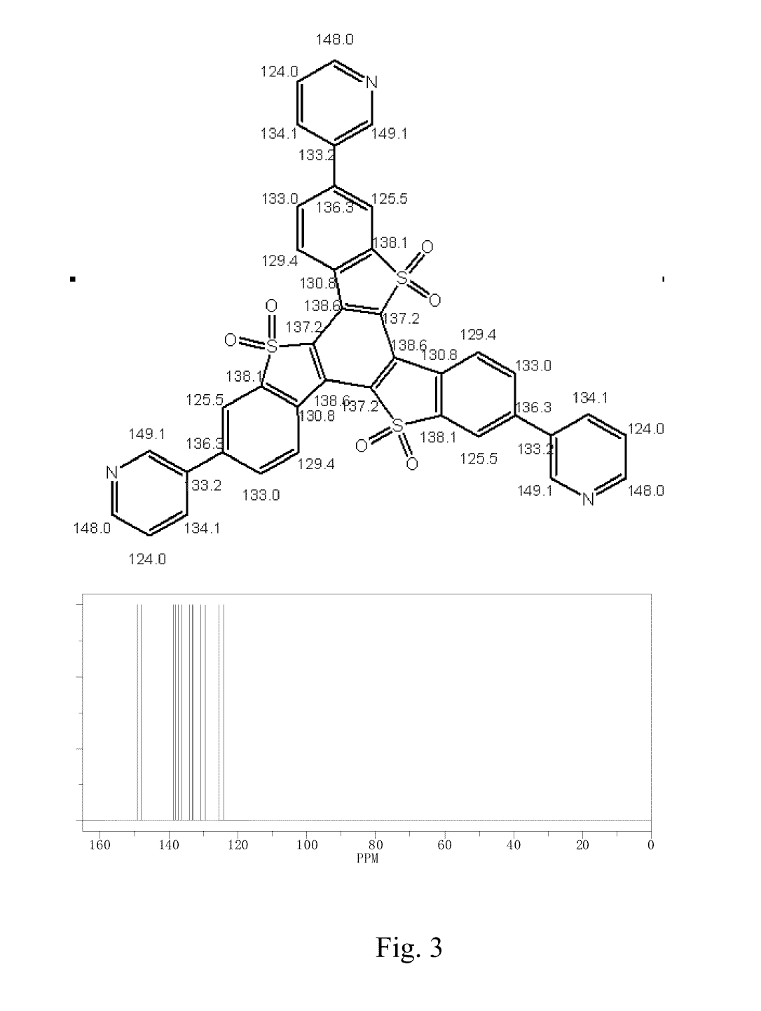

NMR (C-13) spectroscopy is shown in FIG. 3, and NMR data is the result of simulation with Chemdraw2004 software.

It can be seen that main structural atoms of this material (trithiofluorene) are almost disposed on the same plane and have a better space plane property. However, the planes that three pyridine rings and main structure disposed have a predetermined angle, so that crystallinity of the material can be decreased. Molecular weight of 2,2′,2″-tri(3-pyridyl)trithiofluorene (C₃₉H₂₁N₃O₆S₃) is 723. Because of its larger molecular weight, it can be anticipated that the material has a high-glass transition temperature and low-crystallinity, and thus, a relatively stable amorphous film can be obtained and the efficiency of device can be increased, and lifespan of the device can also be extended.

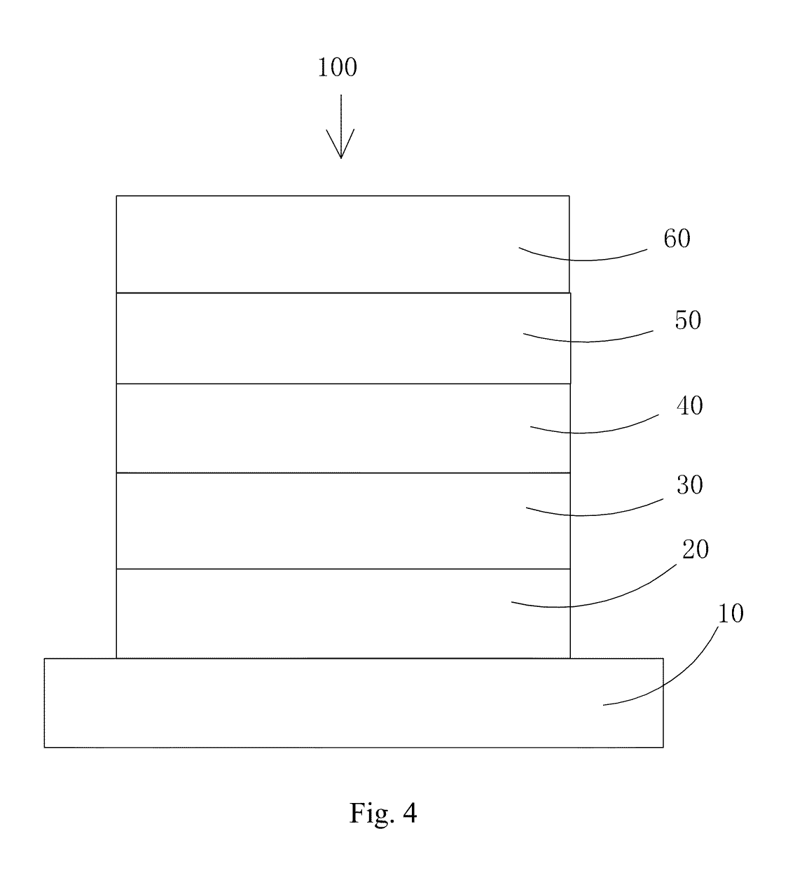

As shown in FIG. 4, the present invention also provides an organic electroluminescent device using sulfonyl group-contained compound. The organic electroluminescent device 100 comprises: a transparent substrate 10, an anode 20 arranged on the transparent substrate 10, a hole transporting layer 30 arranged on the anode 20, a light-emitting layer 40 arranged on the hole transporting layer 30, an electron transporting layer 50 arranged on the light-emitting layer 40, and a cathode 60 arranged on the electron transporting layer 50. At least one of the electron transporting layer 50 and the light-emitting layer 40 contains a sulfonyl group-contained compound. The electron transporting layer 30, the light-emitting layer 40, and electron transporting layer 50 can be a single layer or composed of multiple layers.

The sulfonyl group-contained compound contained in light-emitting layer 40 and electron transporting layer 50 can be arranged according following manner:

When the light-emitting layer 40 comprises the sulfonyl group-contained compound, the sulfonyl group-contained compound can be used as a single host material of the light-emitting layer or can be mixed with other host materials to serve as an ingredient of the host material of the light-emitting layer. When the sulfonyl group-contained compound is used as an ingredient of the host material of the light-emitting layer, the amount thereof is 1%-99% of the total weight of the host material of the light-emitting layer, and is preferably an amount of 5%-95% of the total weight of the host material of the light-emitting layer.

When the electron transporting layer 50 comprises the sulfonyl group-contained compound, the electron transporting layer 50 can be of a single layer. However, to better match energy level of light-emitting layer 40, the electron transporting layer 50 can be composed of at least two layers, and each layer of the electron transporting layer 50 can comprise the sulfonyl group-contained compound. The sulfonyl group-contained compound can used as a single material for the electron transporting layer, or can be doped with other electron transporting material and serving only as an ingredient of the material of the electron transporting layer. When the sulfonyl group-contained compound is used as an ingredient of the material of the electron transporting layer, the amount thereof is 1%-99% of the total weight of the material of the electron transporting layer material, and is preferably an amount of 50%-95% of the total weight of the material of electron transporting layer.

Because sulfonyl group-contained compounds have sulfonyl groups served as electron withdrawing groups, they have a good electron affinity and electron transport property and can serve as an electron transport material in favor of injection and transportation of electrons.

A preferred structure of the sulfonyl group-contained compound is represented by the following formula:

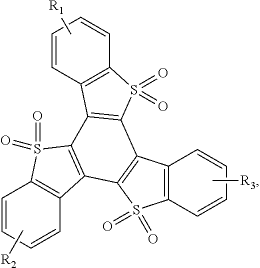

In the above formula, R₁, R₂, and R₃ are an alkyl group, an aromatic ring group, a heterocyclic ring group, —CN or —OCH₃. R₁, R₂, and R₃ are linked in position 2 or 3 of the benzene ring.

Because of dendrimer structure of sulfonyl group-contained compound, it is beneficial for electron injection and transport, so as to increase efficiency of the organic electroluminescent device 100. The compound also has properties of high-molecular weight, high-stereo hindrance, high-glass transition temperature, and low-crystallinity, which are favorable for forming a stable amorphous film to extend the lifespan of the organic electroluminescent device 100.

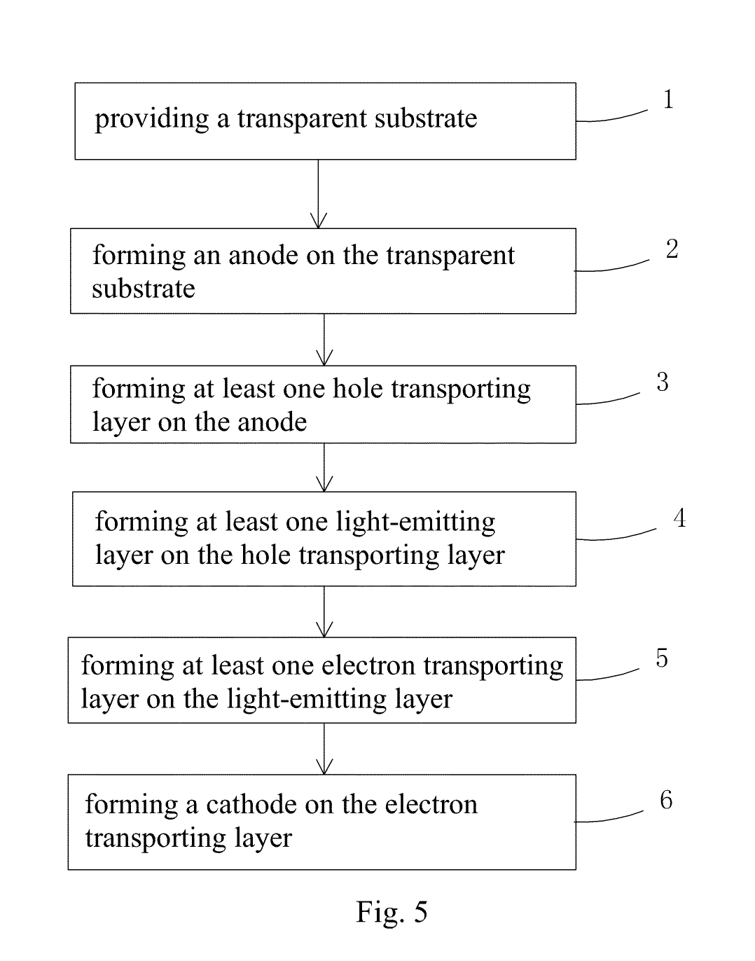

As shown in FIG. 5, the present invention also provide a preparation method of organic electroluminescent device using sulfonyl group-contained compound, which comprises the following steps:

Step 1: providing a transparent substrate 10;

Step 2: forming an anode 20 on the transparent substrate 10;

Step 3: forming one or multiple hole transporting layers 30 on the anode 20;

Step 4: forming one or multiple light-emitting layers 40 on the hole transporting layer 30;

Step 5: forming one or multiple electron transporting layer 50 on the light-emitting layer 40; and

Step 6: forming a cathode 60 on the electron transporting layer 50.

At least one of the light-emitting layer 40 and electron transporting layer 50 comprises the sulfonyl group-contained compound.

When the light-emitting layer 40 comprises the sulfonyl group-contained compound, Step 4 further comprises: depositing the sulfonyl group-contained compound on the hole transporting layer 30 by vacuum evaporation, wherein the sulfonyl group-contained compound can be subjected to evaporation as a single host material of the light-emitting layer, or can be subjected to evaporation with other host material to serve as an ingredient of the host material of the light-emitting layer. The sulfonyl group-contained compound has an amount of 1%-99% of the total weight of the host material of the light-emitting layer, and is preferably an amount of 5%-95% of the total weight of the host material of the light-emitting layer.

When the electron transporting layer 50 comprises the sulfonyl group-contained compound, Step 5 further comprises depositing the sulfonyl group-contained compound, as a material of the electron transporting layer, on the light-emitting layer 40 by vacuum evaporation. To better match the energy level of the light-emitting layer 40, the electron transporting layer 50 can be composed of at least two layers, and each layer of the electron transporting layer 50 can comprise the sulfonyl group-contained compound through vacuum evaporation, or the electron transporting layer 50 can be doped with other electron transporting materials, wherein the sulfonyl group-contained compound is evaporated with the other electron transporting materials to serve as an ingredient of the material of the electron transporting layer. The sulfonyl group-contained compound has an amount of 1%-99% of the total weight of the material of the electron transporting layer, and is preferably an amount of 5%-95% of the total weight of the material of the electron transporting layer.

In summary, the sulfonyl group-contained compound of the present invention combines three thiofluorenes to form a novel sulfonyl group-contained compound with dendrimer structure, which combines properties of electron affinity and electron transportation of thiofluorene together, and also combines the dimension property of dendrimer structure. When the sulfonyl group-contained compound is used for light-emitting layer and electron transporting layer of an organic electroluminescent device, the efficiency and lifespan of the organic electroluminescent device can be increased.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A sulfonyl group-contained compound, represented by the following formula: 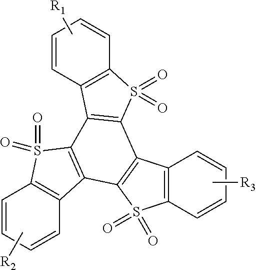
in which R₁, R₂, and R₃ are an alkyl group, an aromatic ring group, a heterocyclic ring group, —CN or —OCH₃; and R₁, R₂, and R₃ are linked in position 2 or 3 of the benzene ring.

2. The sulfonyl group-contained compound as claimed in claim 1, wherein the alkyl group is a branched alkyl group or a linear alkyl group.

3. The sulfonyl group-contained compound as claimed in claim 2, wherein the branched alkyl group is 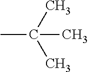
and the linear alkyl group is 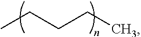
wherein n is an integer of 1 to 8.

4. The sulfonyl group-contained compound as claimed in claim 1, wherein the aromatic group is

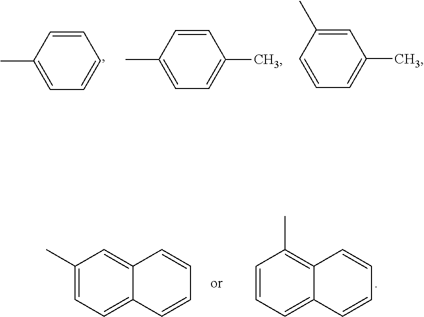

5. The sulfonyl group-contained compound as claimed in claim 1, wherein the heterocyclic ring group is

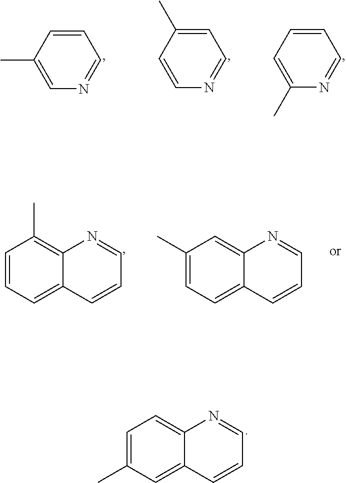

6. An organic electroluminescent device using sulfonyl group-contained compound, comprising: a transparent substrate, an anode arranged on the transparent substrate, a hole transporting layer arranged on the anode, a light-emitting layer arranged on the hole transporting layer, an electron transporting layer arranged on the light-emitting layer, and a cathode arranged on the electron transporting layer; wherein at least one of the electron transport layer and the light-emitting layer comprises the sulfonyl group-contained compound.

7. The organic electroluminescent device using sulfonyl group-contained compound as claimed in claim 6, wherein the sulfonyl group-contained compound is represented by the following formula: 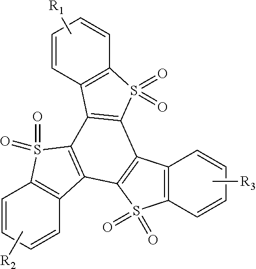
in which R₁, R₂, and R₃ are an alkyl group, an aromatic ring group, a heterocyclic ring group, —CN or —OCH₃; and R₁, R₂, and R₃ are linked in position 2 or 3 of the benzene ring.

8. The organic electroluminescent device using sulfonyl group-contained compound as claimed in claim 6, wherein when the light-emitting layer comprises the sulfonyl group-contained compound, the sulfonyl group-contained compound is used as a single host material of the light-emitting layer or an ingredient of host material of the light-emitting layer; and when the sulfonyl group-contained compound is used as an ingredient of the host material of the light-emitting layer, the compound is in an amount of 1%-99% of the total weight of the host material of the light-emitting layer;
when the electron transport layer comprises the sulfonyl group-contained compound, the electron transport layer comprises a single layer or at least two layers, each layer of the electron transport layer comprising the sulfonyl group-contained compound, the sulfonyl group-contained compound being used as a single material of the electron transport layer or an ingredient of the material of the electron transport layer; when the sulfonyl group-contained compound is used as an ingredient of the material of the electron transport layer, the sulfonyl group-contained compound is in an amount of 1%-99% of the total weight of the material of the electron transport layer.

9. A preparation method of organic electroluminescent device using sulfonyl group-contained compound as claimed in claim 6, comprising the following steps:
(1) providing a transparent substrate;
(2) forming an anode on the transparent substrate;
(3) forming at least one hole transporting layer on the anode;
(4) forming at least one light-emitting layer on the hole transporting layer;
(5) forming at least one electron transporting layer on the light-emitting layer; and
(6) forming a cathode on the electron transporting layer;
wherein at least one of the light-emitting layer and electron transporting layer comprise the sulfonyl group-contained compound.

10. The preparation method of organic electroluminescent device using sulfonyl group-contained compound as claimed in claim 9, wherein step (4) further comprises depositing the sulfonyl group-contained compound on the hole transporting layer by vacuum evaporation, the sulfonyl group-contained compound being used as a single host material of the light-emitting layer or an ingredient of the host material of the light-emitting layer; wherein when the sulfonyl group-contained compound is used as an ingredient of the host material of the light-emitting layer, the sulfonyl group-contained compound is in an amount of 1%-99% of the total weight of the host material of the light-emitting layer.

11. The preparation method of organic electroluminescent device using sulfonyl group-contained compound as claimed in claim 9, wherein step (5) further comprises depositing the sulfonyl group-contained compound that is used as the material of the electron transporting layer on the light-emitting layer by vacuum evaporation, the sulfonyl group-contained compound being used as a single material of the electron transporting layer or an ingredient of the material of the electron transporting layer; wherein when the sulfonyl group-contained compound is used as an ingredient of the material of the electron transporting layer, the sulfonyl group-contained compound is in an amount of 1%-99% of the total weight of the material of the electron transport layer.
